(19) United States
(12) Patent Application Publication
(10) Pub. No.: US 2006/0081995 A1
(43) Pub. Date: Apr. 20, 2006

(54) Soldered material, semiconductor device, method of soldering, and method of manufacturing semiconductor device

(75) Inventors: Toshihide Takahashi, Yokohama-shi (JP); Shuichi Komatsu, Yokohama-shi (JP); Masahiro Tadauchi, Ota-ku (JP); Kazutaka Matsumoto, Yokohama-shi (JP); Izuru Komatsu, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/176,422

(22) Filed: Jul. 8, 2005

(30) Foreign Application Priority Data
Sep. 30, 2004 (JP) 2004-287890

(51) Int. Cl. H01L 23/48

(52) U.S. Cl. 257/772

(57) ABSTRACT

A soldered material according to an aspect of the present invention comprises a first metallic material to be soldered, a second metallic material to be soldered which is composed of at least one element selected from the group consisting of nickel, palladium, platinum and aluminum, and a soldering layer soldering the first metallic material and the second metallic material, and in a cross-sectional microstructure of the soldering layer a solid solution phase comprising the element constituting the second metallic material and tin is present.

### CROSSREFERENCE TO RELATED APPLICATION

This application is based upon and claims the benefit of priority from the prior Japanese Patent Application No. 2004-287890, filed on Sep. 30, 2004; the entire contents of which are incorporated herein by reference.

### BACKGROUND

1. Field of the Invention

The present invention relates to soldering material suitably used especially for soldering between parts of electronic device, between metallic materials, between non-metallic material metallized with metal on the surface and metallic material, between non-metallic materials metallized with metal on the surface, a method of soldering, a semiconductor device using the same, and a method of manufacturing the semiconductor device.

2. Description of the Related Art

A solder joint technology which is a soldering technology using a certain substance and another substance having a melting point lower than that of the former substance has been used generally and also used extensively for soldering electronic equipment to solder semiconductor elements and electronic parts such as microprocessors, memory chips, resistors, and capacitors with a mounting board. Solder joint has features that parts are mechanically fixed to the board and also electrically jointed by containing a metal having conductivity into solder.

Nowadays, with the rapid popularization of personal electronic devices and equipment such as personal computers, cellular phones and the like, the selection of soldering material or a method of soldering in a packaging technology of electronic parts has become of increasing importance.

Conventionally, tin-lead based eutectic solder has frequently been used because it is quite suitable for practical use. However, lead contained in the tin-lead based eutectic solder is harmful for human. Therefore, so-called lead-free solder which does not contain lead is demanded to be developed in a short time.

On the other hand, in soldering material used at present in semiconductor devices, for instance, used in a power device, a low-temperature type solder (Sn—Pb eutectic solder) of which melting point is about 183° C., and a high-temperature type solder (Pb-5Sn solder) of which melting point is about 300° C. have been mainly and selectively used depending on respective processes.

As for the low-temperature type solders of the two, mainly tin-silver-copper based alloy has reached in a practical stage and it is expected that many set makers will complete replacement into lead-free solders in several years.

However, as for a high-temperature type solder, namely, soldering material to form a soldered portion to maintain good mechanical strength even at high temperatures, for instance, at 260° C., a promising candidate material except high lead content material has not been found yet.

When intending to develop a metal alloy having a melting point of about 300° C. using metallic material not containing harmful substance such as lead or the like, making a tin based alloy containing mainly tin with a melting point of 232° C. into a material having a higher melting point, making a zinc based alloy containing zinc with a melting point of 420° C. into material having a lower melting point and the like are conceivable. However, soldering material capable of forming a soldered portion which can have both mechanical strength and good soldering property at high temperatures has not been found from development of these alloys.

As a technology of forming a soldered portion which can maintain good mechanical characteristics under high temperature conditions, a method of changing a soldered portion into an intermetallic compound to improve heat-resistance has been proposed, for instance, “Reactivity to form intermetallic compounds in the micro joint using Sn—Ag solder” by T. Yamamoto, et al. (13th Micro Electronics Symposium research papers (2003), pp. 45-48) and “Evaluation of Reactivity between Sn—Ag Solder and Au/Ni—Co Plating to Increase the Melting Temperature of Micro Joints” by T. Yamamoto, et al. (10th Symposium on “Microjoining and Assembly Technology in Electronics”, 10(2004), pp. 117-122).

The above methods, however, have a drawback that these methods need to change the whole interface of the soldered portion into an intermetallic compound, which requires a long duration time to allow the compound sufficiently grow, for instance, about 30 minutes to one hour for mounting the device. Besides, there also is a drawback that, due to brittleness of intermetallic compound, mechanical reliability of the soldered portion is inferior and it is feared that thermal conductivity and electric resistance will be deteriorated.

### SUMMARY

The present invention provides a soldered material which can form a soldered portion capable of maintaining good mechanical strength in a short time even under a high-temperature condition by using a soldering material containing substantially no lead; a method of soldering; a semiconductor device which can achieve soldering in a short time using a soldering material containing substantially no lead so that the soldered portion of a semiconductor element and a lead frame can maintain good mechanical strength even under a high-temperature condition; and a method of manufacturing the semiconductor device.

According to an aspect of the present invention, there may be provided a soldered material comprising a first metallic material to be soldered, a second metallic material to be soldered, disposed near the first metallic material, and substantially formed of at least one element selected from the group consisting of nickel, palladium, platinum and aluminum, and a soldering layer soldering between the first metallic material and the second metallic material, wherein in a cross-sectional microstructure of the soldering layer a solid solution phase comprising the element constituting for the second metallic material and tin is present. The cross-sectional microstructure of the soldering layer further has plural intermetallic compound phases having at least one element constituting the second metallic material and tin as constituent elements.

In the soldered materials, it is desirable that the first metallic material is substantially formed of at least one element selected from the group consisting of nickel, palladium, platinum and aluminum. In these soldered materials, it is more desirable that the first metallic material is substantially formed of nickel or platinum. Besides, in these soldered materials, it is desirable that the second metallic material is substantially formed of nickel or platinum.

According to another aspect of the present invention, there may be provided a semiconductor device, comprising a semiconductor element having a first surface metallized with a metallic thin film; a metallic lead frame having a second surface for mounting the semiconductor element, the second surface being substantially formed of at least one element selected from the group consisting of nickel, palladium, platinum and aluminum, a soldering layer interposed between the first surface of the semiconductor element and the second surface of the metallic lead frame, to solder the semiconductor element and the metallic lead frame and having in the cross-sectional microstructure of the soldering layer a solid solution phase including at least one element constituting the second metallic material and tin, and plural intermetallic compound phases having at least one element constituting the second metallic material and tin as constituent elements, and a sealing resin which seals the semiconductor element and the lead frame. In the semiconductor device, it is desirable that the metallic thin film is substantially formed of at least one element selected from the group consisting of nickel, palladium, platinum and aluminum. And, in the semiconductor device, it is more desirable that the metallic thin film is substantially formed of nickel or platinum.

According to still another aspect of the present invention, there may be provided a method of soldering, comprising laminating a first metallic material and a second metallic material which is substantially formed of at least one element selected from the group consisting of nickel, palladium, platinum and aluminum and has a thickness of at least 0.1 μm or more, by interposing a thin layer soldering material formed of tin or tin alloy and having a thickness in the range of 0.1 μm to 130 μm to form a laminate, and heating the laminate at a temperature in the range of 265° C. to 450° C. to mutually solder the first metallic material and the second metallic material.

In the method of soldering, it is desirable that the tin alloy is selected from the group consisting of a tin-silver based alloy mainly composed of tin and silver, a tin-silver-copper based alloy mainly composed of tin, silver and copper, a tin-copper based alloy mainly composed of tin and copper and a tin-zinc based alloy mainly composed of tin and zinc, and other tin based alloys. In the method of soldering, it is desirable that the first metallic material is substantially formed of at least one element selected from the group consisting of nickel, palladium, platinum and aluminum. In the method of soldering, it is more desirable that the first metallic material is substantially formed of nickel or platinum.

According to still another aspect of the present invention, there may be provided a method of manufacturing a semiconductor device, comprising laminating a semiconductor element, which has a first surface metallized with a metallic thin film, and a lead frame having a second surface for mounting the semiconductor element, the second surface for mounting the semiconductor element being substantially formed of at least one element selected from the group consisting of nickel, palladium, platinum and aluminum, the lead frame having a thickness of 50 μm or more, wherein between the first surface of the semiconductor element and the second surface of the lead frame opposed to each other, a thin layer soldering material of tin or tin alloy having a thickness in the range of 0.1 μm to 300 μm is interposed to form a laminate, heating the laminate at temperature in the range of 265° C. to 450° C. to solder the semiconductor element and the lead frame to each other, and sealing the soldered semiconductor element and lead frame with a resin.

In the method of manufacturing the semiconductor device, it is desirable that the tin alloy is selected from the group consisting of a tin-silver based alloy mainly composed of tin and silver, a tin-silver-copper based alloy mainly composed of tin, silver and copper, a tin-copper based alloy mainly composed of tin and copper and a tin-zinc based alloy mainly composed of tin and zinc, and a liquidus line temperature of the tin alloy is 232° C. or less. In the method of manufacturing the semiconductor device, it is desirable that the metallic thin film is at least one element selected from the group consisting of nickel, palladium, platinum and aluminum. In the method of manufacturing the semiconductor device, it is more desirable that the metallic thin film is substantially formed of nickel or platinum.

According to the aspects of the present invention, for example, when nickel is used as the second metallic material, its liquidus line rises to about 350° C. when nickel forms solid solution by about 1% only as shown in the Ni—Sn phase diagram of FIG. 7. Therefore, when tin or a tin alloy having a liquidus-line temperature of, for example, 232° C. or less is interposed between the first metallic material and the second metallic material (nickel), and heated, the tin or the tin alloy melts at 232° C. When the temperature is further raised, the nickel melts to have the composition of solid solution corresponding to that temperature to form a soldering layer having a high melting point, it is partly precipitated as an intermetallic compound in the cooling process to form a soldering layer having remarkable heat resistance, which has fine particles of the intermetallic compound dispersed in the Sn—Ni solid solution.

The second metallic material remained without melting becomes a barrier layer with respect to the substrate copper to suppress the reaction between copper and the tin alloy and to enhance the stability of the soldered interface with the lead frame, chip electrode and the like. To form a soldering layer having a high melting point, the soldering layer of the semiconductor device has a thickness of 0.1 to 300 μm, preferably 1 to 100 μm, and more preferably 1 to 50 μm, and the metallized layer of the semiconductor element such as nickel has thickness in a range of 0.1 to 5 μm. Where gold metallization is conducted, its thickness is preferably about 100 nm. The heating temperature is desired to be the melting point or more of the tin or the tin alloy and not to exceed 450° C. which is the softening temperature of the lead frame, and more preferably about 350° C.

The soldered material according to one aspect of the present invention has a sufficient soldering strength even if a harmful high-lead-containing soldering material is not used and can also maintain a mechanical strength even under a high temperature condition.

According to a method of soldering of another aspect of the present invention, a soldered portion having high heat resistance can be formed by using a tin based soldering material without using a harmful high-lead-containing soldering material even if a time of maintaining at a soldering peak temperature is short.

Specifically, soldering can be made in a short time according to the method of soldering another of aspect of the present invention, contributing to the improvement of the production efficiency of the soldered material. For example, in a real semiconductor device mounting process, the production speed can be set to the same level as the present production speed using lead-containing solder, and the production efficiency is prevented from lowering.

According to a method of manufacturing a semiconductor device and the semiconductor device according to aspects of the present invention, a soldering strength between the semiconductor element and the lead frame can be maintained even if exposed to a high temperature condition and a highly reliable semiconductor device can be produced in a short time even if a harmful high-lead-containing soldering material is not used in the semiconductor device production process. Therefore, the present invention is quite useful industrially and in view of environmental protection measures.

### BRIEF DESCRIPTION OF THE DRAWINGS

FIG. 1 is a cross-sectional view showing a soldered material of one embodiment of the present invention.

FIG. 2 is a cross-sectional schematic view showing soldering layer of another embodiment of the present invention.

FIG. 3A through FIG. 3D are cross-sectional views showing a method of soldering of another embodiment of the present invention.

FIG. 4 is a cross-sectional view showing another method of soldering of another embodiment of the present invention.

FIG. 5 is a cross-sectional view showing a soldered mode between a semiconductor element and a lead frame of another embodiment of the present invention.

FIG. 6 is a cross-sectional view showing a soldered mode between a semiconductor element and a lead frame of still another embodiment of the present invention.

FIG. 7 is a phase diagram showing a liquidus line in a range of Sn 90-100 of an Ni—Sn binary alloy.

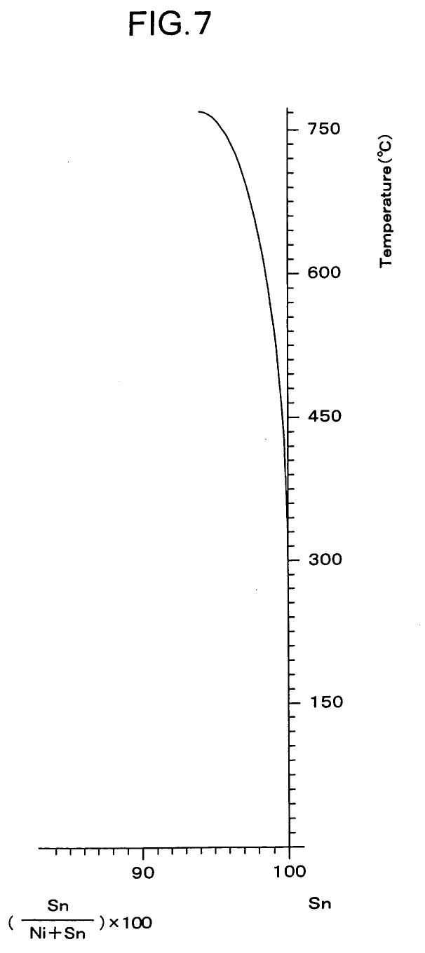

FIG. 8 is a front view showing a semiconductor device of another embodiment of the present invention.

FIG. 9 is a cross-sectional view taken along a cut surface of the semiconductor device of FIG. 8.

FIG. 10 is an enlarged cross-sectional view of the sectional view of FIG. 9.

### DETAILED DESCRIPTION

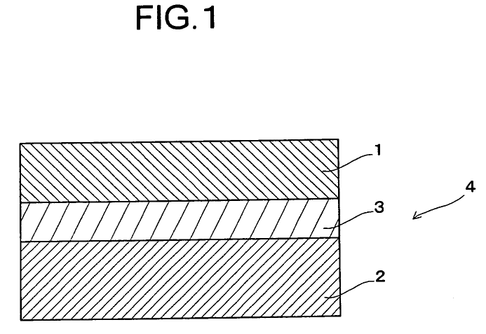

FIG. 1 is an enlarged sectional view showing a soldered material which has a first metallic material 1 soldered to a second metallic material 2 with a soldering layer 3 interposed between them according to one embodiment of the present invention.

In this embodiment, a metallic material is used for the first metallic material 1. The used metallic material can be selected depending on uses and is not limited to a particular one. However, it is desirable to use a material such that when it is dissolved and diffused into melted tin under a high-temperature condition, the solidus-line temperature of a tin alloy formed as a result of forming solid solution into tin does not drop considerably. Specifically, the first metallic material 1 is desirably formed of at least one element selected from the group consisting of nickel, palladium, platinum and aluminum in the same manner as the second metallic material described later. An alloy of those metals can also be used. Among these metals, it is particularly desirable to use an element selected from the group consisting of nickel and platinum. By using these metals, a soldered portion excelling in heat resistance can be formed. It is more desirable to use nickel because its use facilitates formation of a tin alloy and it is also used industrially. In addition to the above-described metals, germanium, niobium, manganese, copper, iron, silver and an iron-nickel alloy, e.g., Fe-42Ni alloy, are preferable materials. The first metallic material is not required to be formed of a single metallic material and may be, for example, a metal-metal clad material or a metal-ceramics composite material. In any case, the present invention can be applied if the soldering surface side is formed of any of the above-described metals.

It is essential to use at least one element selected from the group consisting of nickel, palladium, platinum and aluminum for the second metallic material 2 and it is selected depending on uses. When dissolved and diffused in a tin-containing soldering material by heating at a high temperature, such an element dissolves into tin and can increase sharply a liquidus-line temperature of a tin alloy formed. And, an alloy of these metals can also be used. Among these metals, nickel and platinum are particularly desirable in view of the increase of the liquidus line of the tin alloy, and nickel which is a metal usable industrially is more desirable. The second metallic material is not required to be formed of a single metallic material and may be formed of, for example, a metal-metal clad material or a metal-ceramics composite material. In either case, the present invention can be applied if the soldered surface side is formed of the above-described metal.

In the cross-sectional structure of the soldering layer 3 which solders the first metallic material 1 and the second metallic material 2, a tin base phase, namely a solid solution phase containing the element constituting the second metallic material and tin is present.

The soldering layer 3 is originally a tin base phase, which is low melting point temperature metal, but becomes a tin alloy having a liquidus-line temperature of 300 to 400° C. or more by dissolving the element constituting the second metallic material or the element constituting the first metallic material. By configuring in this way, even if the soldering layer 3 has a high temperature, namely even if it is positioned under a temperature condition of 260° C., the soldering layer 3 as a whole is not formed into a liquid phase but maintains a solid-liquid coexistence state with a liquid phase and a solid phase mixed. Thus, the soldered portion is provided with improved heat resistance.

When the entire soldering layer becomes an intermetallic compound, the soldered portion comes to have a high melting point, but the intermetallic compound itself has high brittleness, so that the soldered portion becomes brittle and its mechanical strength has a possibility of degrading. However, the intermetallic compound is dispersed in the solid solution in the present invention, so that the soldered portion having a high mechanical strength and good heat resistance can be obtained.

When an intermetallic compound phase to be crystallized is in the form of the needles, it becomes a cause of cracks in the soldered portion, and the mechanical strength might not be maintained. However, the intermetallic compound formed in the soldered portion according to the present invention has a scallop or granular form as described below and does not cause such a problem.

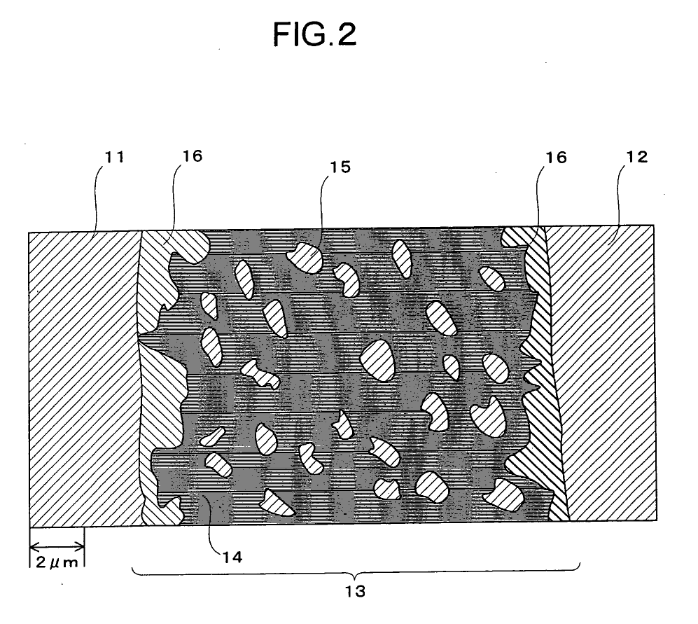

A cross-sectional schematic view showing an example of the soldering layer 3 is shown in FIG. 2. A soldering layer 13 shown in FIG. 2 shows schematically the results of SIM (Scanning Ion Microscope) observation on a cross section of the soldered material obtained as described below. This soldered material is obtained by using a nickel plate having a thickness of 300 μm used as the first metallic material and the second metallic material, forming a laminate with a tin foil interposed as the soldering material between the first metallic material and the second metallic material, and heating the laminate under conditions of a heating time of 30 seconds and a peak temperature (350° C.) for 5 seconds.

Specifically, as shown in FIG. 2, the soldering layer 13 between a first metallic material 11 and a second metallic material 12 has therein a solid solution phase 14 which has nickel as a component element of at least the first or second metallic material dissolved in tin and a tin phase 15 which does not contain the element constituting the second metallic material. And, a scallop intermetallic compound phase 16 which has the element constituting the first and/or second metallic material and tin as constituent elements is present in the interface between the first metallic material 11 or the second metallic material 12 and the soldering layer 13.

In the soldered material according to an embodiment of the present invention, the scallop intermetallic compound phase, which has the element constituting the first and/or second metallic material and tin as the constituent elements, may be present or not in the interface between the first metallic material or the second metallic material and the soldering layer. However, if the scallop intermetallic compound is excessively large in amount, a soldering strength might be decreased, so that its amount is desirably as small as possible. Specifically, its average thickness is desirably a half or less of the thickness of the average soldered portion.

The example shown in FIG. 2 has the second metallic material formed of a single element, but when the second metallic material is formed of at least two elements, the solid solution phase which contains the elements constituting the second metallic material and tin may contain the elements constituting the second metallic material in part or in all.

In the example shown in FIG. 2, the same type of material is used for the first metallic material and the second metallic material, but when a different type of material is used for the first metallic material and the second metallic material, the solid solution phase which contains the element constituting the second metallic material and tin may further contain the element constituting the first metallic material in part or in all.

When a different type of material is used for the first metallic material and the second metallic material, a granular intermetallic compound which has the element constituting the second metallic material and tin as the constituent elements may further contain the element constituting the first metallic material in part or in all.

Besides, when a different type of material is used for the first metallic material and the second metallic material, the soldering layer may have therein a phase containing the first metallic material and tin and a granular intermetallic compound phase which has the element constituting the first metallic material and tin as the constituent elements.

The granular intermetallic compound phase is desirably present at an area ratio from 5% to 20% in a range of the soldering layer being observed. In this area ratio, the soldered portion can maintain a mechanical strength, and the effect of improving the heat resistance is high.

The granular intermetallic compound phase desirably has an average particle diameter from 0.1 μm to 5 μm in the range to be observed. In this average particle diameter, the effect of improving the heat resistance of the soldered portion is high.

The granular intermetallic compound phase is not limited to a particular form. In order to enhance the heat resistance, it is more desirable that a ratio of a minor axis to a major axis is in a range of 1:1 to 1:3. And, the granular intermetallic compound phase may have an uneven surface.

The above-described soldered material can be obtained by conducting a method of soldering described in detail below. However, this method is not exclusive.

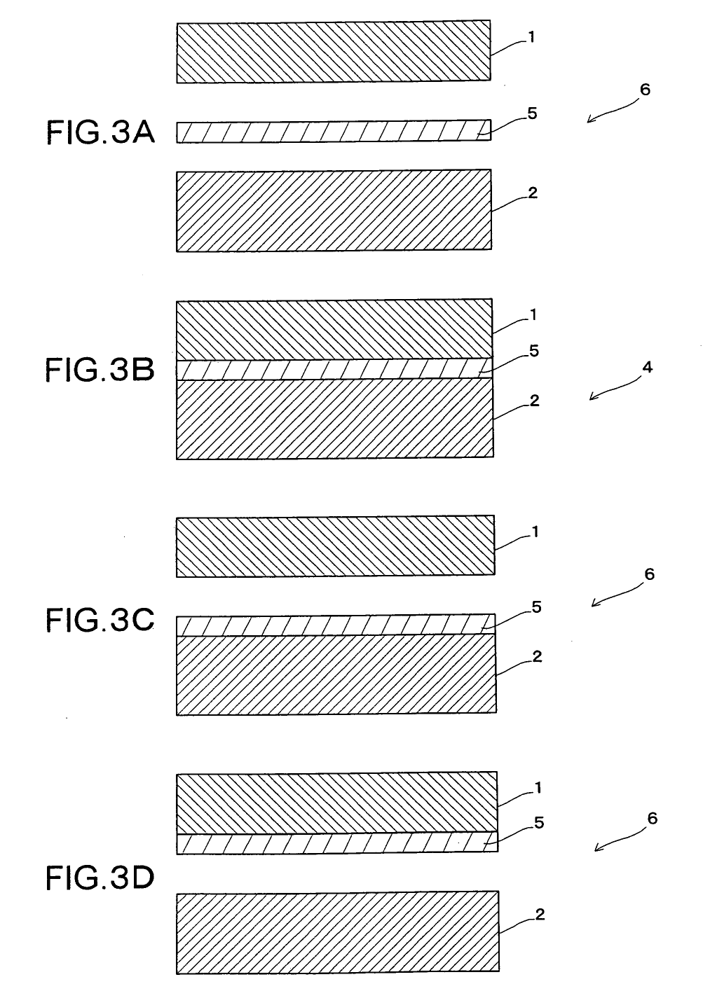

FIG. 3A through FIG. 3D are cross-sectional views showing a method of soldering according to another embodiment of the present invention. As shown in FIG. 3A, the first metallic material 1, a thin layer soldering material 5 and the second metallic material 2 are laminated to form a laminate 6. At this time, a pressure may be applied.

Then, the laminate 6 is heated to obtain a soldered material 4 which has the first metallic material 1 and the second metallic material 2 soldered with the soldering layer 3 interposed between them as shown in FIG. 3B.

To obtain the laminate 6, the thin layer soldering material 5 is previously metallized on the surface of the second metallic material 2 as shown in FIG. 3C, and the first metallic material 1 may be laminated on the thin layer soldering material 5 which is adhered to the surface of the second metallic material 2 to form the laminate 6. As shown in FIG. 3D, the laminate 6 may also be formed by previously metallizing the surface of the first metallic material 1 and laminating the second metallic material 2 on the thin layer soldering material 5 which is adhered to the surface of the first metallic material 1.

A case where the first metallic material or the second metallic material is metallized on the surface of another member which is formed of metal, ceramics, a semiconductor or the like, and the pertinent member is used as a member for soldering to another member is also included in the category of the present invention.

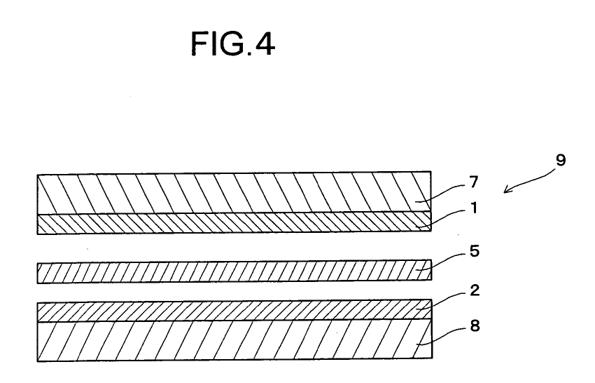

FIG. 4 is a cross-sectional view showing another method of soldering according to another embodiment of the present invention. In this embodiment, the first metallic material 1 is matallized on the surface of a base material 7 and the second metallic material 2 is metallized on the surface of a base material 8. The thin layer soldering material 5 is disposed between the metallized layers to configure a laminate 9. Then, the laminate 9 is heated to conduct soldering. Where the base material 8 and the metallized layer 2 are formed of at least one element selected from the group consisting of nickel, palladium, platinum and aluminum, the laminate of the base material 8 and the metallized layer 2 forms the second metallic material.

FIG. 4 shows an example where both the first metallic material and the second metallic material are metallized on the surface of other base materials respectively, but a case where only the first metallic material is metallized on the surface of one base material and the second metallic material is not metallized on the surface of another base material is also included in the category of the present invention. Conversely, a case where only the second metallic material is metallized on the surface of one base material and the first metallic material is not metallized on the surface of another base material is also included in the category of the present invention.

As means for metallizing the first and second metallic materials on the surface of other members, there are vapor deposition, plating processing, electron beam processing, etc., for example, sputtering.

The members to be used for the above-described method of soldering will be described furthermore. A metallic material is generally used for the first metallic material 1. The metallic material can be selected depending on uses and is not limited to a particular one, but it is desirably a material which dissolves into tin when it is dissolved and diffused in melted tin under a high temperature condition and does not considerably decrease the solidus-line temperature of the tin alloy to be formed. Specifically, when the material is desirably selected from the group consisting of nickel, palladium, platinum and aluminum in the same manner as the second metallic material described later, a soldered portion excelling in heat resistance can be formed. It is desirable that the material is selected from the group consisting of nickel and platinum. An alloy of these metals can also be used. It is desirable to use nickel or platinum and more desirable to use nickel which is metal usable industrially. In addition to the above metals, for example, germanium, niobium, manganese, copper, iron, silver and an iron-nickel alloy, such as Fe-42Ni alloy, can be used appropriately.

For the second metal soldering material 2, a material selected from the group consisting of nickel, palladium, platinum and aluminum is used. An alloy material of them can also be used. These elements when dissolved and diffused into a thin layer soldering material containing tin by heating at a high temperature can sharply increase the liquidus-line temperature of the tin alloy to be formed. Among them, nickel and platinum are particularly desirable in view of a rise in liquidus line of the tin alloy. A case where elements such as gold and silver which are easily dissolved and diffused into melted tin containing soldering material are presented between a second metallic material and a soldering layer is also included in the category of the present invention.

The first metallic material is a metallic material other than a material selected from the group consisting of nickel, palladium, platinum and aluminum, the thickness (average thickness) of the first metallic material is desirably in a range of 0.1 μm to 500 Mm. When the first metallic material is a material selected from the group consisting of nickel, palladium, platinum and aluminum, the thickness is desirably in a range of 0.1 μm to 100 μm.

The second metallic material is required to have a thickness (average thickness) of 0.1 μm or more. If it is less than 0.1 μm, the element does not diffuse sufficiently into the tin alloy in the soldering layer, and there is a possibility that the soldered portion having heat resistance cannot be formed. And, it is desirable that the second metallic material has a thickness of 500 μm or less.

For example, in a case where the metallized layer 2 is formed on the base material 8 as shown in FIG. 4 and the base material 8 and the metallized layer 2 are formed of at least one element selected from the group consisting of nickel, palladium, platinum and aluminum, the laminate of the base material 8 and the metallized layer 2 is assumed to be the second metallic material 2, and the total thickness of the metallized layer 2 and the base material 8 is advisably 0.1 μm or more.

For example, in a case where the metallized layer 2 is formed on the base material 8 as shown in FIG. 4, when the base material 8 is formed of a material other than the material selected from the group consisting of nickel, palladium, platinum and aluminum and the second metallic material 2 is metallized on the base material 8 to solder the base material 8 as shown in FIG. 4, the thickness is 0.1 μm or more, and desirably 1 μm or less.

For example, in a case where the metallized layer 2 is formed on the base material 8 as shown in FIG. 4, even if the base material 8 is formed of a material selected from the group consisting of nickel, palladium, platinum and aluminum and the metallized layer 2 is a material other than the material selected from the group consisting of nickel, palladium, platinum and aluminum, the laminate of the base material 8 and the metallized layer 2 is determined as the second metallic material 2 and the base material 8 may have a thickness of 0.1 μm or more if the metallized layer is formed of a material, such as gold, silver, having high solubility into the melted tin and has a thickness of 1 μm or less. A case where elements such as gold and silver which are easily dissolved and diffused into melted tin containing soldering material are presented between nickel layer and tin layer is also included in the category of the present invention.

For the thin layer soldering material, tin or tin alloy is used. For the tin alloy, a tin-silver based alloy mainly composed of tin and silver, a tin-silver-copper based alloy mainly composed of tin, silver and copper, a tin-copper based alloy mainly composed of tin and copper, and a tin-zinc based alloy mainly composed of tin and zinc are desirable. It is desired that the tin alloy has a liquidus-line temperature of 232° C. or less. Specific examples of compositions of the tin alloy having a liquidus-line temperature of 232° C. or less will be described below.

Tin-silver based alloy: Ag 0.1 wt % or more and 4.0 wt % or less, the rest of Sn.

Tin-copper based alloy: Cu 0.1 wt % or more and 1.0 wt % or less, the rest of Sn.

Tin-silver and copper based alloy: Ag 0.1 wt % or more and 4.0 wt % or less, Cu 0.1 wt % or more and 1.0 wt % or less, the rest of Sn.

Tin-zinc based alloy: Zn 0.1 wt % and 12.0 wt % or less, the rest of Sn.

In addition, these alloys may contain 0 wt % or more and 10 wt % or less of elements such as copper, zinc, nickel, bismuth, indium and antimony.

It is desirable that the thin layer soldering material has a thickness from 0.1 μm to 300 μm, preferably from 1 μm to 100 μm, more preferably from 1 μm to 50 μm, still more preferably from 3 μm to 15 μm, and most preferably from 5 μm to 10 μm to appropriately satisfy the realization of securing of a soldering property of the soldering material and the improvement of the heat resistance by diffusion of the metallic material to be soldered. If the thin layer soldering material is excessively thick, the metallic material to be soldered is not dispersed adequately into the soldering material within the soldering time and the heat resistance might not be improved, and if it is excessively thin, wettability of the soldering material is degraded, and a soldering strength might not be secured.

As means for providing a thin layer, there are plating treatment, solder paste, sheet solder, wire solder, solder pre-coating by evaporation, ion sputtering, a super-juffit method or a super-solder method, and the like.

Where solder paste is used and its thickness is excessively increased, the metallic material to be soldered is not diffused sufficiently into the tin-based layer section in several seconds of soldering time, and an improvement of the heat resistance not be realized. Therefore, to appropriately satisfy the realization of the high melting point in a short time, it is desirable that the paste thickness is set to a range of 50 to 100 μm, and more preferably 50 to 80 μm to decrease the thickness as small as possible.

Where the sheet solder material is used and a sheet thickness is made extremely large, it is conceivable that the metallic material to be soldered is not diffuse sufficiently into the tin-based layer section in several seconds of soldering time, and an improvement of the heat resistance is not realized. Therefore, to appropriately satisfy the realization of an improvement of the heat resistance in a short time, it is desirable that the sheet thickness is set to a range of 30 to 50 μm to decrease the thickness as small as possible.

The method of soldering according to another embodiment of the present invention will be described. Where the laminate is heated, a heating temperature is in a range of 265° C. to 450° C. In this range, a thin layer soldering material mainly composed of tin having a melting point of 232° C. melts, the second metallic material which maintains a solid phase state dissolves and diffuses into the thin layer soldering material so as to form a solid solution in tin. The heating temperature is preferably in a range of 300° C. to 450° C., preferably in a range of 350° C. to 400° C. It is more desirable to heat to about 350° C.

The heating time (particularly, heating time at a peak temperature) is desirably 5 seconds or more. The heating time is more preferably in a range of 5 seconds to 2 minutes, still more desirably in a range of 5 seconds to 1 minute, and most preferably in a range of 5 seconds to 30 seconds. The heating temperature and the heating time may be the heating temperature and the heating time for the laminate in the production of a semiconductor device.

According to the method of soldering of another embodiment of the present invention, the second metallic material having a specific composition and the thin layer soldering material having a specific composition are heated at a high temperature of 265° C. or more to melt the thin layer soldering material which is mainly composed of tin having a melting point of 232° C. and to dissolve and diffuse at least the second metallic material, which holds the solid phase state, into the thin layer soldering material. Within the soldering layer, the second metallic material constituent element dissolves in tin and the liquidus-line temperature of the tin alloy to be formed increases sharply. Thus, the soldered portion can be made to have an improvement of the heat resistance. In other words, the tin phase portion having a low melting point is removed, so that for assurance of 260° C. which is required for the high temperature mount material, the heat resistance of the soldering layer can be maintained under a high temperature condition of 260° C. In the thin layer soldreing material, the intermetallic compound phase or the like, which is configured of tin and at least the second metallic material constituent element, may be produced in addition to the phase having the second metallic material constituent element melted into tin on the soldering layer which is formed by the diffusion of at least the second metallic material. As a result, the soldered material having good mechanical strength can be obtained in a short time even under a high temperature condition.

The soldered material and the method of soldering according to the embodiment of the present invention may be used in any field but used particularly suitably to solder an electronic equipment part, or a part of a semiconductor device and particularly a power semiconductor device which is placed under a high temperature condition in the production process or when the product is used. Especially, it is particularly suitably used to solder a semiconductor element and a lead frame.

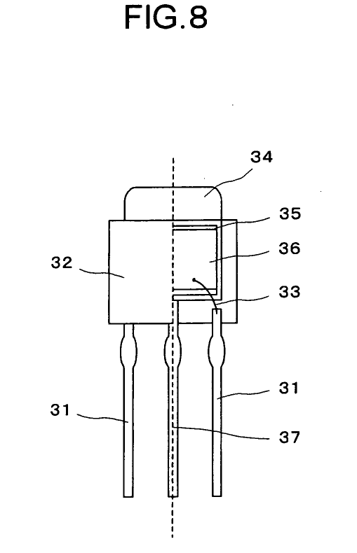

FIG. 8 is a front view showing a semiconductor device of another embodiment of the present invention. The right half of the semiconductor device of FIG. 8 is a perspective view which is used to facilitate the understanding of the semiconductor device. The semiconductor device of this embodiment is comprised of leads 31, a sealing resin 32, a wire 33, a lead frame 34 having a lead section 37, a soldering layer 35 and a semiconductor element 36. The two leads 31 each are connected to the semiconductor element 36 through the wire 33. The lead section 37 of the lead frame 34 is disposed between the two leads 31. The two leads 31 and the lead section 37 function as, for example, an emitter, a base and a collector, respectively.

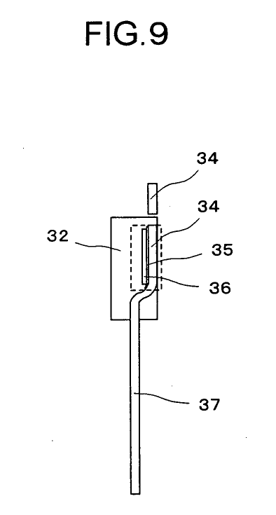

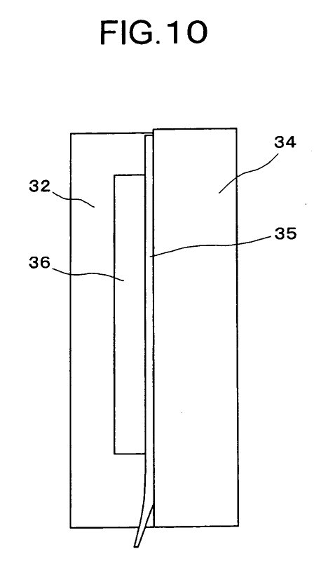

FIG. 9 is a cross-sectional view taken along a cut surface, which is indicated by a broken line, of the semiconductor device of FIG. 8. FIG. 10 is an enlarged cross-sectional view of the broken line section of the sectional view of FIG. 9.

As apparent from FIG. 9 and FIG. 10, this semiconductor device comprises the semiconductor element 36, the lead frame 34 on which the semiconductor element is mounted, the soldering layer 35 for soldering the semiconductor element 36 and the lead frame 34, and the sealing resin 32 which seals the semiconductor element 36, the lead frame 34 and the soldering layer 35. For example, the lead frame 34 may be silver-plated. Examples of the semiconductor device according to another embodiment of the present invention include a diode, a transistor, a capacitor, a thyristor and the like.

In a method of manufacturing the semiconductor device according to another embodiment of the present invention, an appropriate pressure may be applied.

### EXAMPLES

The present invention will be described in detail with reference to examples below.

### Example 1

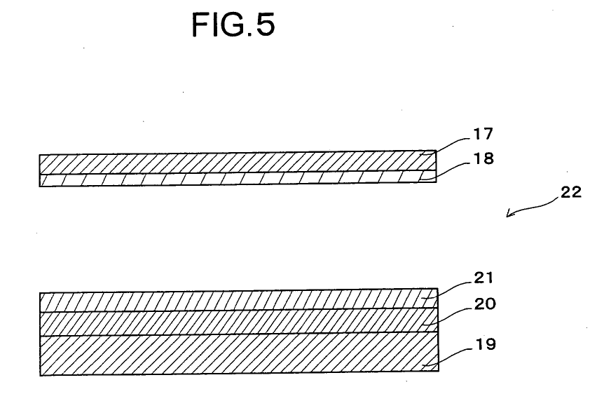

The semiconductor element and the lead frame of a power semiconductor device were soldered. FIG. 5 is a cross-sectional view showing a soldered mode of the semiconductor element and the lead frame. In this power semiconductor module, a 10-mm square silicon semiconductor element 17 was metallized by vapor deposition of gold as a first metallic material to form a metal layer 18 of 0.1-μm thick gold. And, a 0.5-μm thick nickel thin layer 20 was formed as a second metallic material on a lead frame 19 of copper by electron beam processing. Then, a 5-μm thick tin thin layer 21 was formed as a thin layer soldering material on the nickel thin layer 20 by nonelectrolytic plating. The silicon semiconductor element 17 to which the metal layer 18 was adhered and the lead frame 19 which had the tin thin layer 21 adhered to the thin nickel plated layer 20 were laminated such that the metal layer 18 and the tin foil layer 21 were contacted to each other and soldered by applying heat. Heating was conducted on a hot plate in a forming gas (nitrogen+hydrogen) atmosphere which had an oxygen concentration of 100 ppm or less. The heating was conducted at 350° C. for 5 seconds.

SEM (Scanning Electron Microscopy) observation on a cross section of the soldered interface after soldering indicated no formation of conspicuous voids, suggesting a good soldering property.

Lastly, the soldered lead frame and the semiconductor element were sealed with a resin to obtain a power semiconductor device having heat resistance of 250° C.

### Example 2

This example was conducted to obtain a power semiconductor device in the same manner as in Example 1 except that a nickel thin layer 20 was formed on a lead frame 19 by nonelectrolytic plating and a thin layer soldering material 21 was formed thereon by painting solder paste.

Atin-silver based alloy composed of 3.5 wt % of silver and the rest of tin was used to prepare about 5-μm solder powder. The solder powder material and flux were thoroughly mixed in a weight ratio of about 10% in the whole to prepare solder paste. The flux components include a solvent, rosin, an activator, organic halogen, a thickening agent and the like. The solder paste was stirred for about 20 minutes until its viscosity became about 500000 cps which was suitable for printing. This solder paste was printed in thickness of about 80 μm on the nickel thin layer 19 formed by the nonelectrolytic plating, the semiconductor element 21 which had the metal layer 17 of gold formed by vapor deposition was mounted on it, and heating was conducted on a hot plate in a forming gas (nitrogen+hydrogen) atmosphere which had an oxygen concentration of 100 ppm. The heating was conducted at 350° C. for 5 seconds.

SEM observation on a cross section of the soldered interface after soldering indicated no formation of conspicuous voids, suggesting a good soldering property.

Lastly, the soldered lead frame and the semiconductor element were sealed with a resin to obtain a power semiconductor device having heat resistance of 250° C.

### Example 3

This example was conducted to obtain a power semiconductor device in the same manner as in Example 1 except that the thin layer soldering material 21 was formed on the lead frame 19 on which the nickel thin layer 20 was formed by nonelectrolytic plating by supplying a sheet solder material. The sheet solder material was a sheet having a thickness of about 50 μm formed of a tin-silver based alloy composed of 1.0 wt % of silver and the rest of tin. This sheet solder material was placed on the copper lead frame 19, a silicon semiconductor element which was undergone gold evaporation was mounted on it, and heating was conducted on a hot plate in a forming gas (nitrogen+hydrogen) atmosphere which had an oxygen concentration of 100 ppm. The heating was conducted at 350° C. for 5 seconds.

SEM observation on a cross section of the soldered interface after soldering indicates no formation of conspicuous voids, suggesting a good soldering property.

Lastly, the soldered lead frame and the semiconductor element were sealed with a resin to obtain a power semiconductor device.

### Examples 4 to 9, Comparative Example 1

Soldered materials were obtained as follows. The soldered materials of Examples 4 to 9 were prepared by heating nickel thin layers having a thickness of 0.5 or 1 μm formed on a copper plate having a thickness of 300 μm by nonelectrolytic plating and a tin plate having a thickness of 300 μm

Table 1 shows thin layer soldering materials and heating conditions (peak temperature x peak temperature keeping time) of the individual examples. The obtained soldered materials were observed for void conditions by a microfocus X-ray inspection apparatus to evaluate the soldered conditions, and the results are also shown as void ratio in Table 1. The void ratio shown in Table 1 is used to indicate an area ratio of a portion having a good soldered condition in the entire soldered area. The results of SEM observation on the cross sections of the soldered portions of the obtained soldered materials are also shown in Table 1.

[image]

In Examples 4 through 9, as indicated by the results of SEM observation in Table 1, the soldering layers have a tin base phase and dendritic and granular intermetallic compound phases. And, it is apparent that the soldered materials of Examples 4 through 9 having these soldering layers have remarkable soldering strength at a high temperature.

The soldered material of Comparative Example 1 was prepared by heating a copper plate having a thickness of 300 μm and a tin plate having a thickness of 300 μm under the conditions shown in Table 1. It had Kirkendall voids in the interface between the copper plate and the soldering layer.

### Examples 10 through 12

The metallization treatment was conducted in the same manner as in Example 1 by gold evaporation on a 10-mm square silicon semiconductor element. Separately, samples were prepared by forming palladium, platinum and aluminum which were the second metallic material on a copper lead frame in thickness of 0.5 μm by electron beam processing. Then, the tin layer was formed in thickness of 5 μm on the second metallic material of each of the samples by nonelectrolytic plating. The metallized surface of the silicon semiconductor element was soldered to the tin layer formed surface of the lead frame under the same conditions as those in Example 1. For the individual samples, SEM observation on a cross section of the soldered interface after soldering indicates no formation of conspicuous voids, suggesting a good soldering property.

### Examples 13

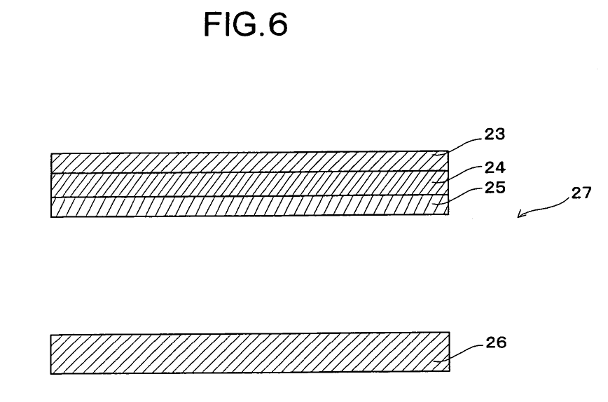

The semiconductor element and the lead frame of a power semiconductor device were soldered in a different manner from Example 1. FIG. 6 is a cross-sectional view showing an another soldered mode of the semiconductor element and the lead frame. In this power semiconductor module, a 10-mm square silicon semiconductor element 23 was metallized by vacuum deposition of nickel as a second metallic material to form a metal layer 24 of 0.5-μm thick nickel. Then, a 10-μm thick tin thin layer 25 was formed as a thin layer soldering material 25 on the nickel thin layer 24 by vacuum deposition. The silicon semiconductor element 23 to which the nickel layer 24 and tin thin layer 25 were adhered and the lead frame 26 were laminated such that the tin thin layer 25 and the lead frame 26 were contacted to each other and soldered by applying heat. Heating was conducted on a hot plate in a forming gas (nitrogen+hydrogen) atmosphere which had an oxygen concentration of 100 ppm or less. The heating was conducted at 350° C. for 5 seconds.

### Examples 14

Soldered material was obtained as follows. The copper plate was metallized by vacuum deposition of nickel as a second metallic material to form a metal layer of 0.5-μm thick nickel. Then, a 10-μm thick tin thin layer was formed as a thin layer soldering material on the nickel thin layer by vacuum deposition. The tin thin layer and an another copper plate were laminated such that the tin thin layer and the another copper plate were contacted to each other and soldered by applying heat. Heating was conducted on a hot plate in a forming gas (nitrogen+hydrogen) atmosphere which had an oxygen concentration of 100 ppm or less. The heating was conducted at 350° C. for 5 seconds.

To measure solidus-line temperatures and liquidus-line temperatures, about 10 mg of samples were undergone thermal analysis by a differential scanning calorimeter (DSC (Differential Scanning Calorimetry): Seiko Instruments Inc., DSC220C). Measuring conditions were a heating rate/cooling rate of 5° C./minute and a peak temperature of 500° C. according to JIS Z 3198-1, Method of test for lead-free solder, Chapter 1: Melting temperature range measuring method. The results are shown as the melting point of the soldered portion at each soldering temperature in Table 2.

TABLE 2

| Soldering | Solidus-line | Liquidus-line |
|---|---|---|
| Temperature (° C.) | Temperature (° C.) | Temperature (° C.) |
| 250 | 231.8 | — |
| 300 | 230.1 | — |
| 350 | 230.1 | 249.8 |
| 400 | 231.4 | 307.9 |
| 450 | 229.7 | 397.5 |

The liquidus-line temperature was obtained at a soldering temperature of 350° C. or more and became high as the soldering temperature was increased. When the soldering temperature was 450° C., the liquidus-line temperature increased to 397.5° C. It seems to indicate that the liquidus-line temperature was increased because of solid solution of Ni or the like. Meanwhile, the solidus-line temperature did not relate to the soldering temperature and had no change. This agrees to the case where the solidus-line temperature is constant even if the Ni amount increases in an Sn-rich range in an Sn—Ni binary phase diagram.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A soldered material comprising:
a first metallic material to be soldered;
a second metallic material to be soldered, disposed near the first metallic material, and substantially formed of at least one element selected from the group consisting of nickel, palladium, platinum and aluminum; and
a soldering layer soldering between the first metallic material and the second metallic material,
wherein in a cross-sectional microstructure of the soldering layer a solid solution phase comprising the element constituting for the second metallic material and tin is present.

2. The soldered material according to claim 1,
wherein the cross-sectional microstructure of the soldering layer further has plural intermetallic compound phases having at least one element constituting the second metallic material and tin as constituent elements.

3. The soldered material according to claim 1,
wherein the first metallic material is substantially formed of at least one element selected from the group consisting of nickel, palladium, platinum and aluminum.

4. The soldered material according to claim 2,
wherein the first metallic material is substantially formed of at least one element selected from the group consisting of nickel, palladium, platinum and aluminum.

5. The soldered material according to claim 1,
wherein the first metallic material is substantially formed of nickel or platinum.

6. The soldered material according to claim 2,
wherein the first metallic material is substantially formed of nickel or platinum.

7. The soldered material according to claim 1,
wherein the second metallic material is substantially formed of nickel or platinum.

8. The soldered material according to claim 2,
wherein the second metallic material is substantially formed of nickel or platinum.

9. A semiconductor device, comprising:
a semiconductor element having a first surface metallized with a metallic thin film;
a metallic lead frame having a second surface for mounting the semiconductor element, the second surface being substantially formed of at least one element selected from the group consisting of nickel, palladium, platinum and aluminum;
a soldering layer interposed between the first surface of the semiconductor element and the second surface of the metallic lead frame, to solder the semiconductor element and the metallic lead frame and having in the cross-sectional microstructure of the soldering layer a solid solution phase including at least one element constituting the material of the metallic lead frame constituting for the second surface for mounting the semiconductor elements and tin, and plural intermetallic compound phases having at least one element constituting the material of the metallic lead frame constituting for the second surface for mounting the semiconductor elements and tin as constituent elements; and
a sealing resin which seals the semiconductor element and the lead frame.

10. The semiconductor device according to claim 9, wherein the metallic thin film is substantially formed of at least one element selected from the group consisting of nickel, palladium, platinum and aluminum.

11. The semiconductor device according to claim 9, wherein the metallic thin film is substantially formed of nickel or platinum.

12. A method of soldering, comprising:
laminating a first metallic material and a second metallic material which is substantially formed of at least one element selected from the group consisting of nickel, palladium, platinum and aluminum and has a thickness of at least 0.1 μm or more, by interposing a thin layer soldering material formed of tin or tin alloy and having a thickness in the range of 0.1 μm to 130 μm to form a laminate; and
heating the laminate at a temperature in the range of 265° C. to 450° C. to mutually solder the first metallic material and the second metallic material.

13. The method of soldering according to claim 12,
wherein the tin alloy is selected from the group consisting of a tin-silver based alloy mainly composed of tin and silver, a tin-silver-copper based alloy mainly composed of tin, silver and copper, a tin-copper based alloy mainly composed of tin and copper and a tin-zinc based alloy mainly composed of tin and zinc, and other tin based alloys.

14. The method of soldering according to claim 12,
wherein the first metallic material is substantially formed of at least one element selected from the group consisting of nickel, palladium, platinum and aluminum.

15. The method of soldering according to claim 12,
wherein the first metallic material is substantially formed of nickel or platinum.

16. A method of manufacturing a semiconductor device, comprising:
laminating a semiconductor element, which has a first surface metallized with a metallic thin film, and a lead frame having a second surface for mounting the semiconductor element, the second surface for mounting the semiconductor element being substantially formed of at least one element selected from the group consisting of nickel, palladium, platinum and aluminum, the lead frame having a thickness of 50 μm or more, wherein between the first surface of the semiconductor element and the second surface of the lead frame opposed to each other, a thin layer soldering material of tin or tin alloy having a thickness in the range of 0.1 μm to 300 μm is interposed to form a laminate;
heating the laminate at temperature in the range of 265° C. to 450° C. to solder the semiconductor element and the lead frame to each other; and
sealing the soldered semiconductor element and lead frame with a resin.

17. The method of manufacturing a semiconductor device according to claim 16, wherein the tin alloy is selected from the group consisting of a tin-silver based alloy mainly composed of tin and silver, a tin-silver-copper based alloy mainly composed of tin, silver and copper, a tin-copper based alloy mainly composed of tin and copper and a tin-zinc based alloy mainly composed of tin and zinc, and a liquidus-line temperature of the tin alloy is 232° C. or less.

18. The method of manufacturing a semiconductor device according to claim 16, wherein the metallic thin film is substantially formed of at least one element selected from the group consisting of nickel, palladium, platinum and aluminum.

19. The method of manufacturing a semiconductor device according to claim 16, wherein the metallic thin film is substantially formed of nickel or platinum.
